(19) United States
(12) Patent Application Publication
(10) Pub. No.: US 2007/0284083 A1
(43) Pub. Date: Dec. 13, 2007

(54) Heat dissipating device

(76) Inventor: Min-Hsien Sung, Taipei County (TW)

Correspondence Address: MIN-HSIEN SUNG, 235 Chung - Ho, Bos 8-24, Taipei, omitted

(21) Appl. No.: 11/443,214

(22) Filed: May 31, 2006

(51) Int. Cl. H05K 7/20

(52) U.S. Cl. 165/80.3; 165/104.33; 228/183; 361/700

(57) ABSTRACT

A heat dissipating device comprises a heat tube; one end of the heat tube being a heated end and another end thereof being a cooling end; at least one side of the cooling end being formed with a plane; each plane being coated with tin glue; and a fin set being formed by a plurality of fins; each fin being formed with a through hole; each through hole having an upper cambered edge, a lower cambered edge, a left side, and a right side; the left and right edges being as correcting edges; one side of the through hole being formed with a flange. In assembly; the plane of the cooling end of the heat tube is coated with tin glue. The cooling end of the heat tube is inserted into the through holes of the fins of the fin set; and the upper and lower edges of the through holes have the effect of correcting the heat tube.

### FIELD OF THE INVENTION

The present invention relates to heat dissipating devices, and in particular to a heat dissipating device with a heat tube and a fin set.

### BACKGROUND OF THE INVENTION

Currently, a plurality of fins are installed to a cooling end of a heat tube. The heated end of the heat tube is assembled with a heat guide block which can be adhered to a surface of a heat source (such as a microprocessor). Thereby heat from the heat source is transferred through the heat guide block, heated end, cooling end to the fin set. Thereby heat can be dissipated effectively.

When above mentioned fin set is combined to the heat tube, each fin of the fin set is formed with a through hole 22. An edge of the through hole is formed with a round hole which is communicated to the through hole. One side of the through hole is formed with a flange which has a shape identical to the through hole. After the cooling end of the heat tube is assembled to the through hole of each fin, a syringe is used to inject tin glue to the through hole through the small round hole so that the tin glue will expand to the gap between the sides of the cooling end of the heat tube and the walls of the through holes so as to increase the heat transfer between the heat tube and the fins. However the expansion of the tin glue is slow and it is difficult to work. Thereby the amount of the tin glue is uncontrollable. Thereby the gap can be filled fully so as to affect the heat transfer rate and the heat tube is easy to loose from the fins.

### SUMMARY OF THE INVENTION

Accordingly, the primary object of the present invention is to provide a heat dissipating device, wherein the cooling end of the heat tube is adhered with tin glue and passes through the through holes. After heating, gaps formed between the heat tube and the two lateral sides will be filled with tin glue. Thus, the outer surface of the cooling end of the heat tube is firmly combined to the walls of the through holes and the flanges of the fins. Thus the heat conduction rate is increase and the heat dissipation is effective.

To achieve above objects, the present invention provides a heat dissipating device which comprises a heat tube; one end of the heat tube being a heated end and another end thereof being a cooling end; at least one side of the cooling end being formed with a plane; each plane being coated with tin glue; and a fin set being formed by a plurality of fins; each fin being formed with a through hole; each through hole having an upper cambered edge, a lower cambered edge, a left side, and a right side; the left and right edges being as correcting edges; one side of the through hole being formed with a flange. In assembly; the plane of the cooling end of the heat tube is coated with tin glue. The cooling end of the heat tube is inserted into the through holes of the fins of the fin set; and the upper and lower edges of the through holes have the effect of correcting the heat tube.

### BRIEF DESCRIPTION OF THE DRAWINGS

FIG. 1 is a schematic perspective view of the heat tube of the present invention.

FIG. 2 is an exploded schematic view of the heat tube and the fin set of the present invention.

FIG. 3 is a schematic view about the assembly of the heat tube and the fin set.

FIG. 4 is a schematic view of FIG. 3.

FIG. 5 is a schematic cross sectional view of FIG. 4, wherein the heat tube is heated.

FIG. 6 is a schematic view of another embodiment of the present invention.

FIG. 7 is a schematic view showing the use of the present invention.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

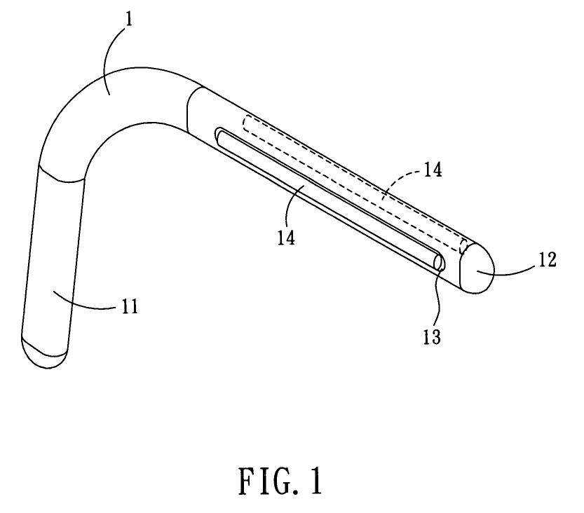

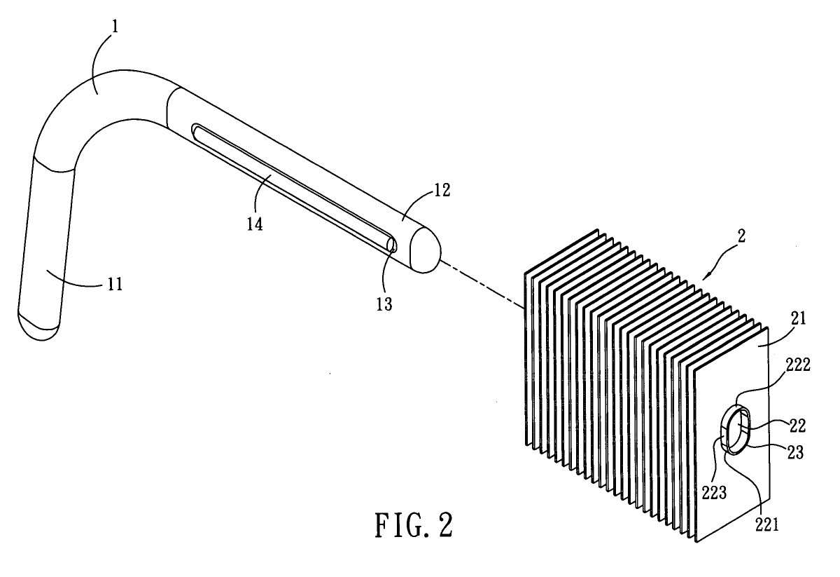

Referring to FIGS. 1 and 2, the structure of the present invention is illustrated. The present invention has the following components.

A heat tube 1 is coated with tin glue 14 which is well controlled so as to be well assembled to the fin set 2. One end of the heat tube 1 is a heated end 11 and another end thereof is a cooling end 12. Each of two sides of the cooling end 12 is formed with a plane 13. Each plane 13 is coated with tin glue 14.

A fin set 2 is formed by a plurality of fins 21. Each fin 21 is formed with an elliptical through hole 22. Each through hole 22 has an upper cambered edge 222, a lower cambered edge 221, a left side 223, and a right side 224. The edges 222 and 221 are as correcting edges. One side of the through hole 22 is formed with a flange 23 which is a shape identical to that of the through hole 22.

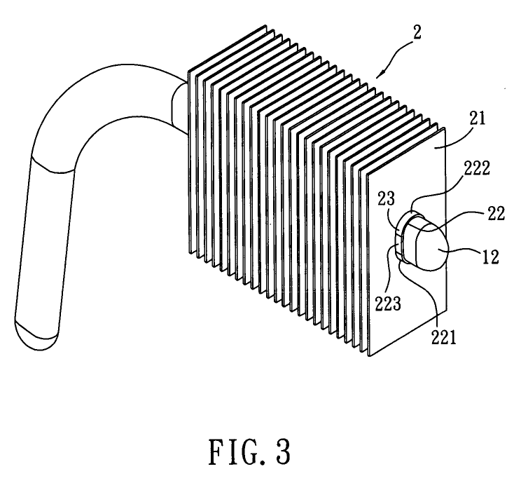

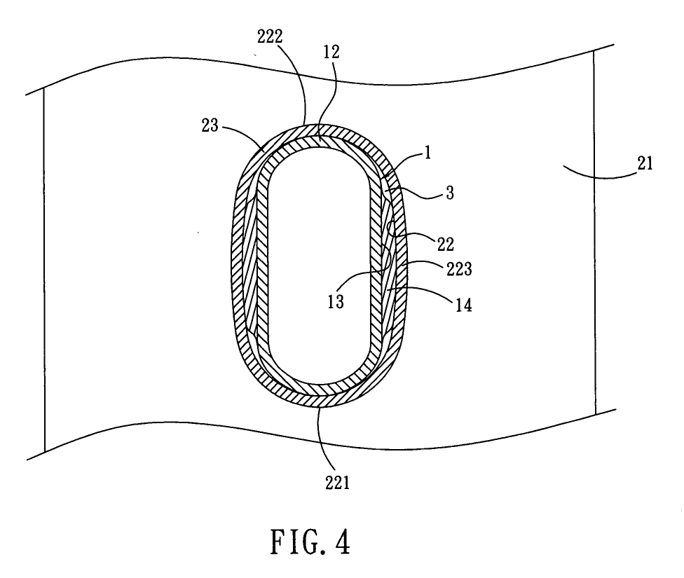

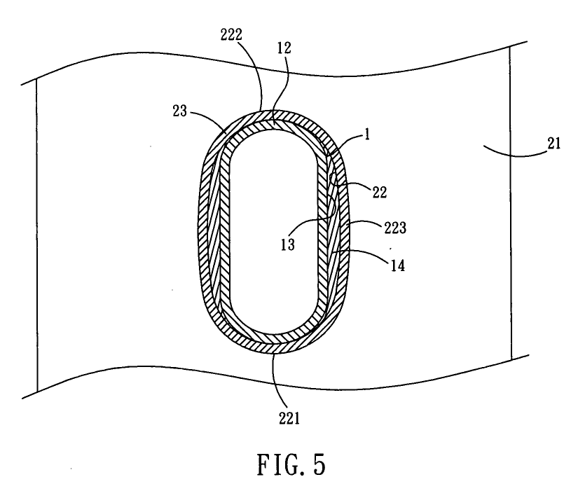

Referring to FIGS. 3, 4 and 5, assembly of the present invention is illustrated. Two planes 13 of the cooling end 12 of the heat tube 1 are coated with tin glue 14. The cooling end 12 of the heat tube 1 is inserted into the through holes 22 of the fins 21 of the fin set 2. The upper and lower edges of the through holes 22 have the effect of correcting the heat tube 1.

After the cooling end 12 of the heat tube 1 passes through the through holes 22 and is heated, gaps 3 formed between the heat tube 1 and the two lateral sides 223, 224 will be filled with tin glue 14. Thus, the outer surface of the cooling end 12 of the heat tube 1 is firmly combined to the walls of the through holes 22 and the flanges 23 of the fins 21. Thus the heat conduction rate is increase and the heat dissipation is effective.

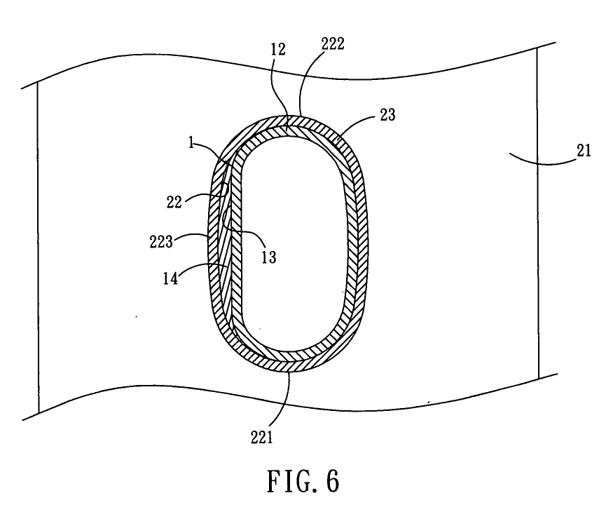

With reference to FIG. 6, a schematic view of another embodiment of the present invention is illustrated. In the following, those identical to the former embodiment will not described here. Only those difference is described herein. As shown in FIG. 6, in this embodiment, only one side of the cooling end 12 is formed with a plane. The tin glue 14 is only coated on the plane 13 and gaps are only formed between the sides 223 and the plane 13. The gaps are filled with tin glue 14. However it also has high heat conductivity.

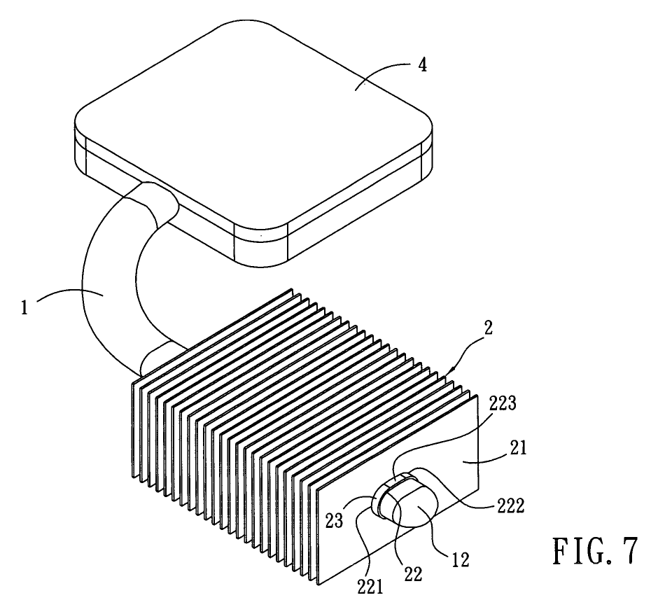

Referring to FIG. 7, the use of the present invention is illustrated. When the cooling end 12 of the heat tube is combined to the fin set 2, the heated end 11 of the heat tube 1 is assembled with a heat guide block 4 which can be adhered to a surface of a heating element (not shown). Thus heat is transferred from a heat source to the heat guide block 4, the heated end 11 of the heat tube 1, the cooling end 12 and then to the fin set 2. Thus heat from the heat source can be dissipated.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A heat dissipating device comprising:
a heat tube; one end of the heat tube being a heated end and another end thereof being a cooling end; at least one side of the cooling end being formed with a plane; each plane being coated with tin glue;
a fin set being formed by a plurality of fins; each fin being formed with a through hole; each through hole having an upper cambered edge, a lower cambered edge, a left side, and a right side; the left and right edges being as correcting edges; one side of the through hole being formed with a flange; and
wherein in assembly; the plane of the cooling end of the heat tube is coated with tin glue; the cooling end of the heat tube is inserted into the through holes of the fins of the fin set; the upper and lower edges of the through holes have an effect of correcting the heat tube.

2. The heat dissipating device as claimed in claim 1, wherein there are two planes at two sides of the cooling end.

3. The heat dissipating device as claimed in claim 1, wherein the flange has a shape identical to that of the through hole.

4. The heat dissipating device as claimed in claim 1, wherein the through hole has an elliptical shape.
